(19) United States
(12) Patent Application Publication
(10) Pub. No.: US 2019/0337023 A1
(43) Pub. Date: Nov. 7, 2019

(54) UNIVERSAL ULTRASONIC RECORD CLEANING DEVICE AND SYSTEM

(71) Applicant: CHARLES BRUNO KIRMUSS, Westminster, CO (US)

(72) Inventor: CHARLES BRUNO KIRMUSS, Westminster, CO (US)

(21) Appl. No.: 16/403,513

(22) Filed: May 4, 2019

Related U.S. Application Data
(60) Provisional application No. 62/762,436, filed on May 4, 2018.

(51) Int. Cl. B08B 3/12

(52) U.S. Cl. CPC B08B 3/12; H01L 21/67057

(57) ABSTRACT

INVENTION RELATES TO A UNIVERSAL DEVICE THAT ATTACHES TO ANY ULTRASONIC CLEANER ALLOWING RECORDS OF MULTIPLE SIZES OR OTHER MEDIA TO BE SLIPPED INTO THE RECORD WASHER INVENTION WHEREIN THE MEDIA RIDES SAFELY ON ROLLERS SPUN BY A MOTOR WHERE THE RECORDS ARE SUSPENDED AT THE CORRECT HEIGHT SO AS NOT TO DAMAGE THE RECORD'S LABEL RESULTING IN SAFE TOTAL CLEANING, AND WHEREIN THE PROCESS-SYSTEM REACHES THE RECORD GROOVES VIA ULTRASONIC FREQUENCIES AND PLASMA TO RESTORE RECORDS AS WELL AS SIMPLY CLEAN THEM.

### CROSS-REFERENCE TO RELATED APPLICATIONS

This application claims priority to U.S. Provisional Utility Application 62/762,436, filed May 4, 2018. The content of the above application is incorporated by reference in its entirety.

### FIELD OF THE DISCLOSURE

Systems and devices for cleaning records and similar media.

### BACKGROUND

Records (LPs, CDs, DVDs and similar optical media) become contaminated, scratched and damaged over time. Customarily, cleaning records' playing surfaces involve turntable-based, vacuum-equipped cleaning machines that use proprietary chemical formulations. Common cleaning solutions consist of isopropyl alcohol, distilled water (avoiding lime-scale deposits) and a surfactant(s) to aid drying. Isopropyl alcohol is customarily used to clean only vinyl records, as isopropyl alcohol may cause permanent damage to shellac recordings, master recordings and one-time recordings (often comprised of acetate, wax and lacquer), including the accidental removal of plasticizers that are part of the record which affects the return of the record's grooves to their original shape and form after being heat generated by the needle's dyne making contact with the record.

Heretofore, insufficient attention has been given to the proper development of “sterilization” machines, to wit, ultrasonic and other solution-based and agitation-based cleaning machines and systems.

Records cleaned in ultrasonic machines benefit from high frequency sound waves' resultant cavitation bubbles, which release contaminants stuck to the records (unwanted debris), but heretofore the development of proper machinery to this end has been lacking. The fact that both the liquid used in the ultrasonic bath has the same charge as the record itself sees such systems only surface clean.

The field of ultrasonic (enzyme solution) record-cleaning requires an apparatus device and associated system that protects against injury and shock, as well as performing proper cleaning and stabilization (holding) of the record in a fashion so as not to damage it. Further, the cleaning also required careful study of reflected standing waves that cancel out the cavitation effect when multiple records are inserted into the ultrasonic bath, negating further the cleanings of the entire record. The instant invention addresses these issues through its revolutionary device and associated method.

### Further Background for the Necessity of the Instant Invention

The necessity for proper cleaning stems from the following:

No matter how one stores and uses either shellacked or vinyl records or other media such as CD/DVD, Optical disks and like media, they inevitably will require maintenance (cleaning). When playing phonograph records, dust particles and contaminants always build up on the stylus as the tone arm moves across the record. This accumulation on the needle “dulls” the sound.

If a new record is played, and where the release agent from, the mold is not removed before first play, a possibility exists where the heat generated by the contact of the stylus with the record groove causing heat will weld dust particles onto the groove, never to be removed again. Thus, the emergence of the dreaded “audible pops” and “crackle sounds” heard are caused by dirt, grime and particles lodged in the record grooves themselves being hit by the needle, amplified by the cartridge. All these conditions are annoying to the listener.

Continual maintenance and care of records by way of regular cleanings reduces the unwanted pops and augments therefore one's listening pleasure and audition, and also protects the quality of the record. Cleaning, while it may not remove unwanted sounds caused by scratches on the record surface, does lower the noise level and removes many of the undesirable sounds created by commitments such as dust that are picked up the turntable or record player's stylus.

Cleaning may be accomplished via simple mechanical method: talking a micro fiber cloth or felt and passing the agent mechanically over the record's groove, with or without chemicals or other cleaning products applied to it. In using any cleaning products and while they require wiping the grooved record surfaces with a soft brush or cloth, residue resides on the record. While not damaging the record's surface per se, and if burned in by the stylus in an un-cleaned record, dirt and grime and other contaminants are first and foremost forced into the record grooves create noise when a record is played. As both the cleaning liquid being applied mechanically using a brush or cloth have the same surface charge, such cleanings are limited to surface cleaning only. Grooves are not reached. Records that are air dried further see a film left on the record which further deaden's the sound. Additionally, even using ultrasonic or vacuum cleaning systems see cleaning agents used prior using other mechanical methods and never properly cleaned using ultrasonic technology may appear to reside on the record's surface also reducing the sound quality.

Regardless, when playing a record cleaned by any of the above methods, one may hear surface noises as well as where the timber and tonality and the emotion of the artist of the record has changed and where the original tonal brilliance of this analog medium is reduced.

Over time and decades of experimentations, many record users as well as companies have discovered where certain ultrasonic cleaning machines may be used and while initially ultrasonic cleaners and their attributes are well known and where surface noises and the resulting noises heard caused by dust particles hitting a record player's or turntable's needle are substantially reduced or eliminated, such cleaners see homemade contraptions and ill-designed record support systems and the use of wrong surfactant agents in these systems which in all intents do not render the desired result of improving a record's condition, fooling the user thinking the media has been cleaned. This in part caused by known current cleaning processes coating the record's grooves further. The needle no longer making proper contact with the groove, now rides over the embedded contaminants such as dust, and dirt groove. Pops are reduced, but brilliance of the record removed. In their poor design, they actually damage the record, and only partially clean the record.

Added marketplace adaptations have shown risk of shock or fire hazard and injury to the user. Many available adaptations or assemblies sold have no electrical or safety approvals. Most, if not all, these adaptations are designed with exposed electrical motors, gears and wires, making the above-risks tangible.

The field of ultrasonic (enzyme solution) record-cleaning requires an apparatus device and associated system that protects against injury and shock, as well as performing proper cleaning and stabilization (holding) of the record in a fashion so as not to damage it. The instant invention addresses these issues through its revolutionary device and associated method.

### SUMMARY OF THE INVENTION

Inter alia, a record washing assembly that sits on virtually any ultrasonic cleaner by using an adapter-plate specific to the washer [or designed as a one piece assembly for a specific washer] with a built-in, protected/covered motor that drives the reduction gears, and wherein the rollers are positioned on the underside-undercarriage of the unit rotating the records. The unit features slots on the top of the assembly to allow one to slip in records of any size into the corresponding slots.

### BRIEF DESCRIPTION OF THE DRAWINGS

The drawings described herein are for illustrative purposes only and illustrate only selected embodiments of the present invention. The enclosed drawings are not intended to limit the scope of the present disclosure.

FIG. 1 is an aerial perspective view of the record-cleaning assembly.

FIG. 2 is an elevational zoomed view of the washer assembly mechanism.

FIG. 3 is an exploded view of the ultrasonic washer assembly and underlying tank.

FIG. 4 is a system flow diagram of the instant novel restoration process.

FIG. 5 is an elevational zoomed view of the washer assembly mechanism.

FIG. 6 is a transparent view of the washer assembly mechanism.

FIG. 7 is a perspective transparent view of the underlying tank, illustrating its housing capacity.

### DETAILED DESCRIPTION OF THE DRAWINGS

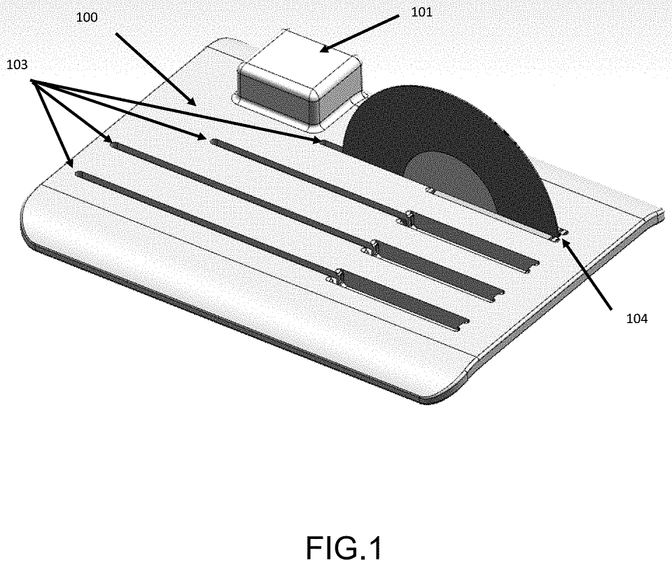

FIG. 1 illustrates the record-cleaning assembly which can be designed to fit any off the shelf ultrasonic washer of 6 liters. Records or medias such as CD/DVD/Optical or hard drive platters of any size depending on the configuration of the assembly and model procured may wash records or media of the same size, or of varying size. Records and the like are inserted (slipped into) the slots shown. The records therein sit at the proper height to have three cleaning fluid cover all recorded media. In case of records, the label does not get wet.

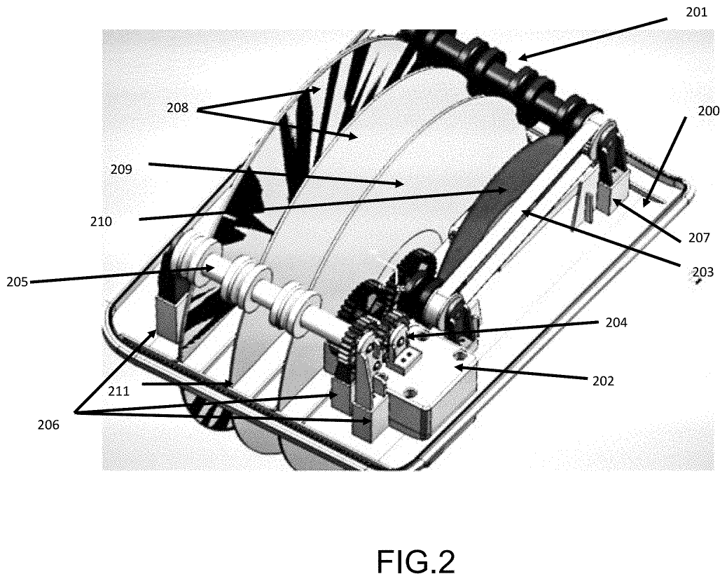

The device comprises of one, two, or more slots that see phonographic records or media that in turn sees records or media easily slipped in when the motor assembly is operating and where the underside roller (as shown in FIG. 2) supports and spins the record. When mounted on top of the ultrasonic cleaning tank (and where by design), [where the basin (tank) tank is filled to the maximum level line], the records (media) sit with all grooves covered by the cleaning liquid, irrespective of size, speed and diameter of the record, based on the record media being inserted in the proper slot.

The height of the roller in the bottom of the assembly itself makes the determination of the actual depth at which other media is then suspended in the tank's cleaning solution for the ultrasonic to then clean at the correct height. As such, the label at the center of the record never is touched, never gets wet.

For example, in the situation of 4 (four) records being cleaned in a 6 (six) liter tank, the spacing is no less than 1.75″ but may vary due to the overall height, width and depth of the tank between records to assure proper cleaning from the ultrasonic generators located at the bottom of the tank. Notwithstanding, using a larger tank size, more records may be added maintaining the total spacing of the record.

The distance (spacing) between multiple records is critical as to assuring the resulting cavitation and implosion of micro-bubbles created by the ultrasonic and the attraction to the record's groove of the resulting plasma wave does not see this effect cancelled by standing waves if records are spaced too closely.

The entire assembly sits securely with no screws or mechanical fastening devices atop the ultrasonic cleaner's tank. The device's motor is powered either by an external power supply that is manually controlled or wired into the ultrasonic devices power system which then sees the motor run when the ultrasonic system is turned on and/or controlled by the ultrasonic's control circuitry and logic.

FIG. 2 illustrates the mechanism of the washer assembly. Records or other medias once slipped in from the top of the assembly being inserted in a slot by the user sees the media whatever type sit safely onto soft rollers of a proper dimension and curve. The rollers are then though various gears are in turn are connected to a shaft and DC or AC powered motor which ultimately then rotates the rollers which in turn then spins the records. The motor may be replaced by a hand crank, driving the gears which then sees the rollers turn which then sees the record or media to be cleaned turn.

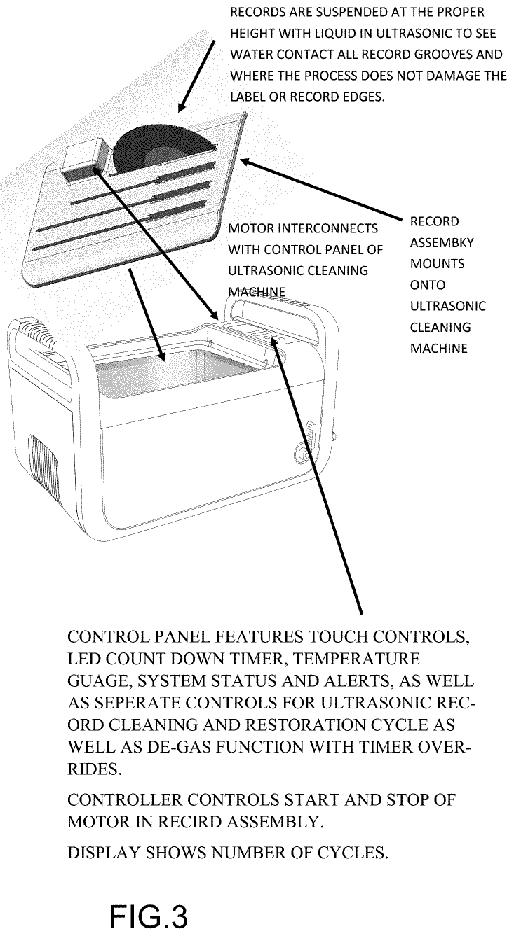

FIG. 3 is further described supra, and is discussed in detail infra.

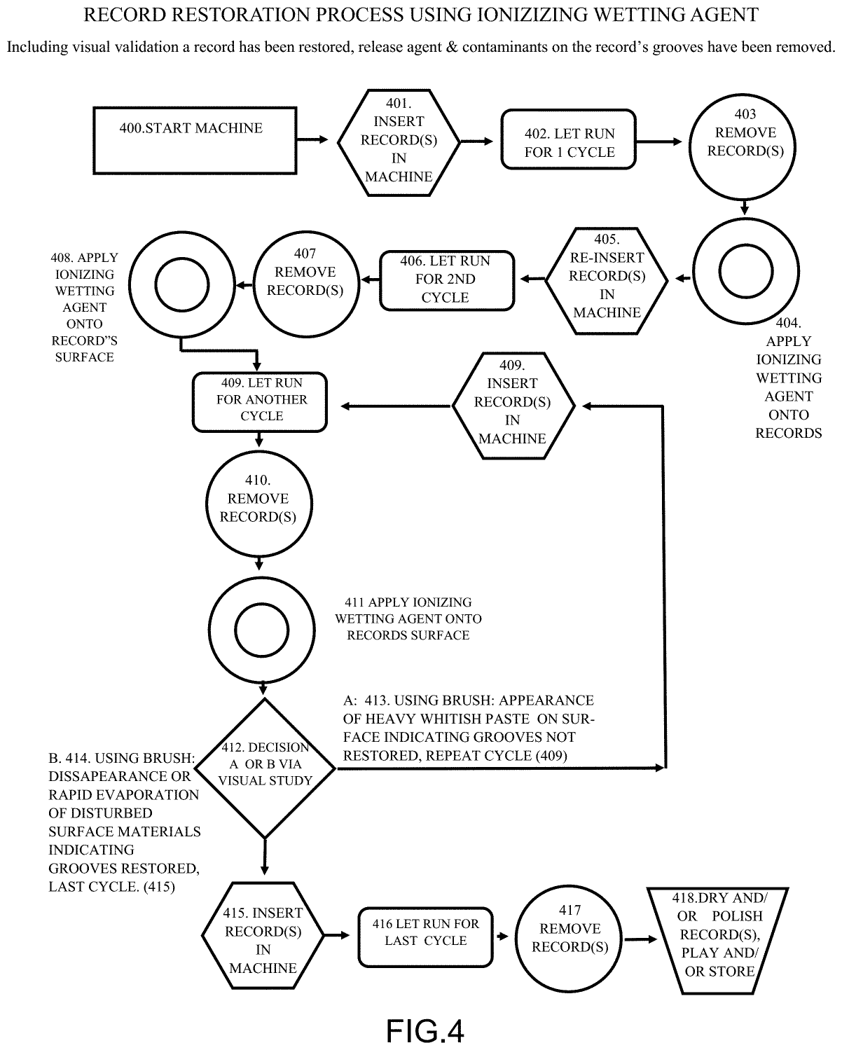

In FIG. 4, we see the attachment assembly of the invention sitting on top of the ultrasonic cleaner.

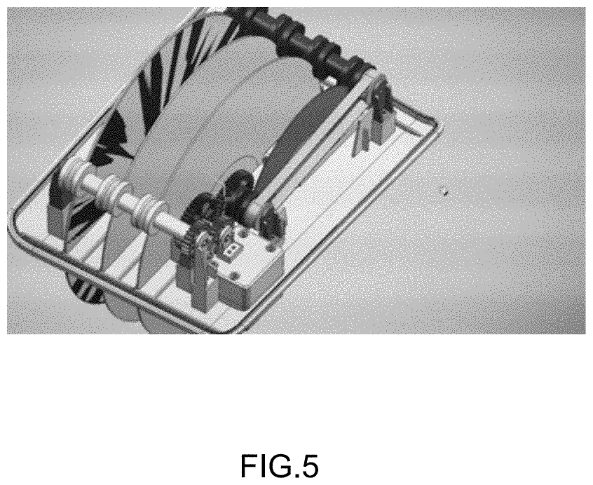

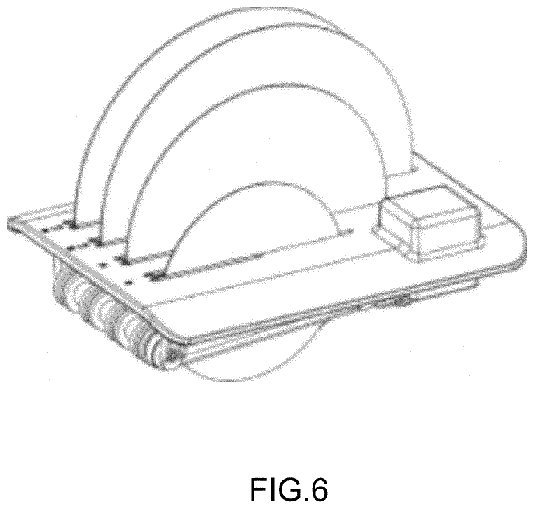

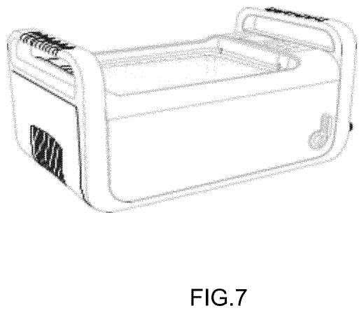

FIGS. 5, 6 and 7 are alternate views of FIGS. 1-3, and are further discussed ad described supra, and are discussed in detail infra.

### System Methodology and Device Use

Rather than re-creating new ultrasonic generator technology and a tank assembly that holds a solution to dip a phonographic record (or CD, DVD, Optical Disk, Hard Dive memory platter, or similarly applicable medium) for cleaning purposes (with or with or without any elaborate controls), the instant invention allows the apparatus device (and their desired media) to be used and attached to any ultrasonic washer basin or unit, suspending the aforementioned medias securely, safely and at the proper height with no user-adjustments. This design leaves no chance for the media to be inserted at the incorrect height.

The invention could also be characterized as an attachment to the cleaning tank that may or may not be connected directly to the control circuitry of any ultrasonic cleaning machine, and thus provides the user with an apparatus for one to safely handle, install and remove the invention from any ultrasonic cleaner. In addition, the user now may efficiently clean the playing surfaces of disc-type records in a very convenient and efficient manner without damaging the record, or surface of the media such as CD, DVD, optical disk.

Multiple records may be washed simultaneously in this device. Furthermore, the engineering and design of the invention takes into consideration the need to clean the record's grooves and/or surface and/or inserted media in its entirety, and to refrain from touching the paper label attached to the record itself.

In addition, in order to clean multiple records at the same time while suspended in an ultrasonic bath, either of the same size or multiple sizes, there are certain elements that this invention considers, all of which are novel points of the invention:

(a) If multiple records are to be cleaned at the same time, there is a need for a minimum space to be retained between records depending on the size of the ultrasonic basin (tank) so as to achieve the complete cleaning of all records by way of ultrasonic cavitation. This specific distance between records is vital to ensure total cleaning of all grooves. With a proper space between records to be maintained: the ultrasonic machine's micro-bubble burst cavitation and resulting plasma effect of cleaning is not reduced as the bubbles rise from the bottom of the ultrasonic basin (tub), reaching the top of the water level in the basin (tub) and thus cleaning the entire records grooves from edge of the record to the end of record (wax removal line).

(b) Where records are known to have different sizes (diameters and widths), current systems may not see all of their grooves (or surfaces of media if media) being cleaned, resulting in “skewer records” when multiple records of varying sizes are cleaned at the same time. Specifically, most media do not see the ultrasonic cleaning fluid contact all of the recorded data/or grooves as does the instant invention by virtue of its engineering and design. Contact alone with the liquid in the tank does not reach the record's grooves and removes the release agent as described thus restoring the record's grooves.

(c) Currently where records of different sizes see their labels damaged by water, as skewering does not see record labels protected, the instant invention solves this issue by virtue of its engineering and design.

(d) Where skewering of records (as a method used by current suspension systems) sees the center hole of the record damaged as well as the label either immediately or over time, as well as providing the potential of warping a record when inserted into a hot ultrasonic solution bath, the instant invention solves this issue by virtue of its engineering and design.

In both cases [above/(d)], with other systems, the record is usually damaged as well as reducing the value of the record for a collector. The instant invention solves this issue by virtue of its engineering and design.

(e) Many current record suspension systems are suspended in the basin or tank of the ultrasonic as termed by the consumer as fragile “Erector sets.” Their design feature exposed parts, exposed motors, and exposed wires. Therefore, addressing the above issues, the instant disc record-cleaning device solves these issues by virtue of its simple construction with a minimal number of parts. The instant invention is also inexpensive to manufacture and maintain, all the while cleaning all the records' grooves (whereas previously-disclosed systems clean only some of the grooves).

The instant device takes care not to thermally damage the record being dipped and then washed by the ultrasonic cleaner. In inferior systems, ultrasonic waves created by the ultrasonic generator itself usually see the liquid in the ultrasonic basin rise by itself. Cavitation creates kinetic energy. Users therein become confused in determining the proper temperature at which the washer should be set. The instant invention solves this issue by virtue of its engineering and design.

In the instant invention, design considerations for the control of the washer are included in this application where the control panel of the machine is made to simplify the user interface with the machine. One-button touch controls are made for starting the ultrasonic wash cycle, of [e.g.] 5 minutes, as well as one button touch control to de-gas water that has imminently been poured into the tank.

For proper operation, a tank recently filled possesses excess air. This air must be removed. In the instant invention, this air-removal is accomplished via its pulse-de-gas function made available with a touch of a button, allowing the sonic generator to pulse at 3 second intervals over a prescribed preset amount of time. (In this setting, [e.g.] 1 minute 36 seconds).

The system must also account for heat and not to overheat the cleaning liquid in the tank, typically distilled water with or without a surfactant added, over 95° F. Records may be damaged by using commercial cleaners so the invention calls out for a user-friendly control panel along with the record assembly, with indicators and alarms.

As water becomes warm, it is important to rotate the records by ways of a mechanical, safe means. A low voltage, fuse-protected DC motor is part of the instant invention's record-washing assembly that then connects to a source of switched power controlled by the user, wired internally into the commercial ultrasonic washer or in an external control.

The entire assembly thus becomes part of the complete system, safe for records as well as safe to use by the user and where records are held securely and where users have no fear or possibility if receiving an electric shock. The instant invention is therefore responding to needs of both the user and in the care of cleaning and restoring vinyl records is described in this application.

The means of supporting and suspending records in a basin of any ultrasonic washing system (basin/tub) is critical so as not to either damage the record itself and to safely clean the record.

The invention described is an improvement over any available known ultrasonic record cleaning system or device in the way it protects users against injury, shock as well as performing proper cleaning and holding the record in a fashion not to damage it, considering now a proper cleaning system.

### Process Steps, Specifications and Considerations

The following addresses the instant invention's ability to restore records as well as cleaning them, removing remnants of oils that bubble out during the process. The agitation of brushing in the ionizing surfactant and charging the record now attract the plasma wave created by cavitation: this is the key principle at work. It allows one to restore the grooves without damaging the record.

As opposed to current sonics which are primarily just a tank filled with a solution (usually distilled water) with soap, the instant invention features: a SYSTEM which improves cleaning inside the record's grooves.

This invention and process allows the cavitation to reach the grooves.

This way, the record has the same “charge.”

The instant method utilizes an ionizing surfactant needs to be brushed (in repeated cycles) in the grooves.

This then attracts the plasma wave created by the cavitation effect.

This ionizing surfactant is washed off in about 3 to 4 minutes based on the speed of the record “revolving” or spinning in the machine.

Thus the instant method demands the user reapply the ionizing surfactant.

The record is then returned to the machine for another process cycle.

This above-cycle, repeated, allows the sonic to attack the contaminants in the grooves.

The process may be described as:

1. As vinyl (PVC) and Shellac records repel water, as both the record and water in the tank have the same electrical change, thus an ultrasonic alone cannot clean or restore record grooves. A method to brush into the grooves an anti-fungal, anti-static, PVC and Shellac friendly water-soluble wetting surfactant that iconizes the record changing charge and thus attracting the plasma wave sees a brush that is less than 30 microns used, fitting the grooves of the record, brushing in a surface ion charge changing agent.

2. The applicator (brush) also per FIG. 4 allows the user to see the progress of the sonic in softening the contaminants found in the grooves;

3. A hand dried brush is used between applications of the ionizing surfactant and is part of the method and process that allows the user to see first the rise and fall of a white pasty material that has been dislodged by the ultrasonic's cavitating micro-bubbles and resulting plasma wave first brought up by the brush and application of the ionizing surfactant.

3. To know when a record's grooves have been restored and release agent has been removed between use of the ultrasonic in repetitive cycles:

4. By using this brush with repeated applications of ionizing surfactants, a decrease/reduction of this visible paste like material or rapid evaporation of the surfactant indicates to the user where there is only one last two to five-minute restoration cleaning cycle. This confirms visually to the user where there are no more release agents or contaminants or other residues left in the record grooves to be removed. The record is ready for polishing.

5. As to removal of films after any cleaning. The document is correct where we are reflecting on the fact where air drying or vacuum drying further affects and negates cleanings whether manual or otherwise as the films left from the cleaning agents are air dried or vacuum dried onto the record. This (above) achieves record-groove restoration.

6. Use of an optician's microfiber cloth to remove any remaining surface water on the record followed by a felt brush where a felt of less than 30 microns is used to polish the record's grooves removing any films or residues left over from the restoration process.

7. A specifically designed plastic or metal support with a felt to suspend the record from touching the workspace area, with a width not to exceed 4½″ and just touching the record label allowing for the application of surface or facilitate the polishing process.

### Further Specifications and Method-Steps for the Instant Device

The record washing assembly (fixture) sits on virtually any ultrasonic cleaner by using an adapter plate specific to the washer or designed as a one piece assembly for a specific washer with a built in protected motor that drives the reduction gears and the rollers underside the unit that rotates the records.

The unit features slots on the top of the assembly that allows one to slip in records of any size into the corresponding slots very easily.

Records that are slipped in are not touched by any mechanism such as skewers that may damage the record, and where records ride safely and securely on roller that do not touch the record groove or other media upon which the audio media or data is recorded. Before slipping in the records an ionizing agent is used brushing in a PVC or shellack friendly surfactant which is part of the process to assure groove cleaning (restoration) and for the first time in use of an ultrasonic attracts the cavitation and plasma wave to inside the groove. Repeated applications also show the user when the groove has been restored and where contaminants and the original record's release agent trapping dust, dirt etc. has been removed.

Records, when they are slipped in irrespective of their size, speed (diameter), do not see their labels touch the cleaning solution in the ultrasonic. No special care or consideration is needed by using this device for protection as it relates to covering the record's label from getting wet. Records and media sit on the rollers underneath the assembly at the correct height based on the slot used. Record edges are not damaged. Only the area containing data or audio is cleaned.

Records when they spin in the cleaner do so at a distance between records that does not affect or cancel out the desired cavitation and micro bubbles rising from the base of the basin (tub) created by the ultrasonic generator and their premature explosion ahead of reaching to the surface in many of the bubbles generated which would then as a result not allow the record area closest to the wax point (center of the record) being cleaned. Further, brushing in of an ionizing surfactant ensures groove cleaning and the removal of the record's release agent resulting in record groove restoration.

A sealed motor assembly with an appropriate motor running at a safe voltage.

A 3.5 mm or like 2 pin waterproof jack that may be connected to a source of external power or directly to the ultrasonic machine. In the latter case, the user then interfaces with the touchscreen control panel of the ultrasonic washer or external control device to start the wash cycle, and in so doing, the command is then passed to the motor itself to start turning the reduction gears and ultimately spin the records that are sitting safely on the rubberized rollers.

A foam or other soft material(s) guide [which may or not be used] to provide a gentle mechanical cleaning action to the surface of the record located in one side of the slot opening.

The guides may be removed for cleaning or replacement without tools.

Interface of a control system that does not overheat water and typically maintains water at a temperature of not more than 95° F. (may be adjusted)

A thermistor control which alerts the user to a dangerous temperature level and/or where an alarm sounds and/or where the ultrachic generator is tuned off.

The record washing assembly sits on top of the ultrasonic washer's basin (tub) securely without the need of any tools for placement, or removal.

The slots are marked onto the plastic cover as to the size of record to be slipped into the slot.

When records are inserted into the slots, the machine then seats them properly in between the guides of the roller support.
Said guides of roller support shown in FIGS. 1-4.;
AND, as additional embodiment, WHEN The process utilizes pre-determined time period ranges from approximately 2 minutes to approximately 5 minutes,
and wherein, depending on the materials to be subject to ultrasonic cleaning, temperature control from 95° F. and alerts thereof may be adjusted,
and wherein 35 KHz is used as the preferred ultrasonic frequency, but said frequency may be adjusted depending on the materials to be cleaned and restored and upon the configuration of the tank and its support fixture configuration, and wherein a plurality of ultrasonic frequencies may additionally be used and selected in a fixed frequency or in a a sweeping range.

### Disclosure and Specifications Generally

In the Summary above and in this Detailed Description, and the Claims below, and in the accompanying drawings, reference is made to particular features (including method steps) of the invention. It is to be understood that the disclosure of the invention in this specification includes all possible combinations of such particular features. For example, where a particular feature is disclosed in the context of a particular aspect or embodiment of the invention, or a particular claim, that feature can also be used, to the extent possible, in combination with and/or in the context of other particular aspects and embodiments of the invention.

Certain terminology and derivations thereof may be used in the following description for convenience in reference only, and will not be limiting. For example, words such as “upward,” “downward,” “left,” and “right” would refer to directions in the drawings to which reference is made unless otherwise stated. Similarly, words such as “inward” and “outward” would refer to directions toward and away from, respectively, the geometric center of a device or area and designated parts thereof. References in the singular tense include the plural, and vice versa, unless otherwise noted.

The term “comprises” and grammatical equivalents thereof are used herein to mean that other components, ingredients, steps, among others, are optionally present. For example, an article “comprising” (or “which comprises”) components A, B and C can consist of (i.e., contain only) components A, B and C, or can contain not only components A, B, and C but also contain one or more other components.

Where reference is made herein to a method comprising two or more defined steps, the defined steps can be carried out in any order or simultaneously (except where the context excludes that possibility), and the method can include one or more other steps which are carried out before any of the defined steps, between two of the defined steps, or after all the defined steps (except where the context excludes that possibility).

The term “at least” followed by a number is used herein to denote the start of a range beginning with that number (which may be a range having an upper limit or no upper limit, depending on the variable being defined). For example, “at least 1” means 1 or more than 1. The term “at most” followed by a number (which may be a range having 1 or 0 as its lower limit, or a range having no lower limit, depending upon the variable being defined). For example, “at most 4” means 4 or less than 4, and “at most 40%” means 40% or less than 40%. When, in this specification, a range is given as “(a first number) to (a second number)” or “(a first number)−(a second number),” this means a range whose limit is the second number. For example, 25 to 100 mm means a range whose lower limit is 25 mm and upper limit is 100 mm.

Aspects of the disclosed invention may be embodied as a system, method or process, or computer program product. Accordingly, aspects of the disclosed invention may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, aspects of the disclosed invention may take the form of a computer program product embodied in one or more computer readable media having computer readable program code embodied thereon.

Any element in a claim that does not explicitly state “means for” performing a specified function, or “step for” performing a specific function is not to be interpreted as a “means” or “step” clause as specified in 35. U.S.C. § 112 ¶6. Specifically, the use of “step of” in the claims herein is not intended to invoke the provisions of U.S.C. § 112¶6.

1. An apparatus for cleaning recording media, the apparatus comprising:
an ultrasonic bath configured to contain a pre-determined quantity of a cleaning agent; and
a holder attachment configured to fit on the ultrasonic bath, the holder attachment comprising a plurality of slots for accommodating a plurality of recording media therein, the holder attachment further configured to securely hold the recording media therein and facilitate rotation of the recording media such that an entire surface area, including all the grooves of the recording media of the recording media, makes contact with the cleaning agent subjected to ultrasonic vibrations in the ultrasonic bath to facilitate the cleaning of the recording media.

2. The apparatus according to claim 1, wherein the recording media includes disc type storage media and the slots on the holder attachment are have varying lengths configured to accommodate recording media of different diameters, wherein the slots are configured on the holder attachment in a spaced apart manner while maintaining a distance of at least 1.75 inches between two successive slots to assure proper cleaning from the ultrasonic generators located at the bottom of the tank by assuring the resulting cavitation and implosion of micro-bubbles created by the ultrasonic and the attraction to the record's groove of the resulting plasma wave does not see this effect cancelled by standing waves if records are spaced too closely.

3. The apparatus according to claim 1, wherein the holder attachment comprises:
a pair of roller arrays configured adjacent each end of the holder attachment, each roller on the pair of roller arrays including a slot for accommodating an edge of the recording media to facilitate rolling of the recording media;
a motor configured adjacent any one end of the holder attachment, the motor being either AC powered or DC powered, or optional to the motor, the apparatus comprises a hand crank to facilitate manual provision of the required rotational drive;
a gear arrangement coupled to the motor and one of the pair of roller arrays; and
a transmission belt assembled between the gear arrangement and remaining one of the roller arrays for transmitting the rotational drive from the motor to the remaining one of the roller arrays.

4. The apparatus according to claim 1, wherein a height of a roller array in a bottom of the assembly of the holder attachment makes the determination of the actual depth at which the recording media is suspended in the cleaning agent for the ultrasonic bath to clean at the correct height, thereby facilitating the label at the center of the recording media to never being touched and thus remaining dry and unhampered.

5. The apparatus according to claim 1, wherein holder attachment has a fastener free assembly configuration.

6. The apparatus according to claim 1, wherein the holder attachment has a configuration to prevent exposed parts, exposed motors, and exposed wires, thereby providing the holder attachments a simple configuration with a minimal number of parts.

7. The apparatus according to claim 1, further comprising a control panel to simplify the user interface with the apparatus by provision of one-touch buttons for:
starting the ultrasonic bath for pre-determined time period;
degassing the cleaning agent in the ultrasonic bath for allowing the sonic generator to pulse at 3 second intervals over a prescribed preset amount of time.

8. The apparatus according to claim 1, wherein the cleaning agent is a distilled water or a mixture of water and a surfactant maintained at a temperature of 95° F. while the recording media is being rotated via the motor that then connects to a source of switched power controlled by the user, wired internally into the commercial apparatus or in an external control.

9. A holder attachment being assemblable on an ultrasonic bath for cleaning of a recording media, the holder attachment comprising:
a pair of roller arrays configured adjacent each end of the holder attachment, each roller on the pair of roller arrays including a slot for accommodating an edge of the recording media to facilitate rolling of the recording media;
a motor configured adjacent any one end of the holder attachment, the motor being either AC powered or DC powered, or optional to the motor, the apparatus comprises a hand crank to facilitate manual provision of the required rotational drive;
a gear arrangement coupled to the motor and one of the pair of roller arrays; and
a transmission belt assembled between the gear arrangement and remaining one of the roller arrays for transmitting the rotational drive from the motor to the remaining one of the roller arrays.

10. The holder attachment according to claim 9, wherein:
a height of a roller array in a bottom of the assembly of the holder attachment makes the determination of the actual depth at which the recording media is suspended in the cleaning agent for the ultrasonic bath to clean at the correct height, thereby facilitating the label at the center of the recording media to never being touched and thus remaining dry and unhampered;
the holder attachment has a fastener free assembly configuration; and
the holder attachment has a configuration to prevent exposed parts, exposed motors, and exposed wires, thereby providing the holder attachments a simple configuration with a minimal number of parts.

11. A process for cleaning recording media, the process comprising:
starting an operation of an ultrasonic bath having a holder attachment assembled thereon for holding the recording media and having a cleaning agent contained therewithin;
loading the recording media onto the holder attachment, thereby facilitating an insertion of the recording media into the cleaning agent contained the ultrasonic bath;
allowing the recording media to be rotated while being partially immersed in the cleaning agent for a first cleaning cycle of a pre-determined time period;
removing the recording media from the holder attachment subsequent to the completion of the first cleaning cycle;
applying, via an applicator, an ionizing surfactant to the recording media, wherein the ionizing surfactant;
reloading the recording media onto the holder attachment, subsequent to the application of the ionizing surfactant, for a second cleaning cycle;
removing the recording media from holder attachment and the reapplying the ionizing surfactant to the recording media for a third cleaning cycle;
repeating the process of ionizing surfactant application and repeating the cleaning cycles until the recording media is thoroughly cleaned.

12. The process according to claim 11, further comprising visually inspecting the recording media subsequent to the application of the ionizing surfactant, wherein appearance of a heavy white paste on the surface of the recording media indicates that the recording media is not clean, and another round of ionizing surfactant application and another cleaning cycle in the ultrasonic bath is required for completely cleaning the recording media.

13. The process according to claim 11, further comprising visually inspecting the recording media subsequent to the application of the ionizing surfactant, wherein a decrease/reduction of the visible heavy white paste like material or rapid evaporation of the surfactant indicates to the user where there is only final two to five-minute restoration cleaning cycle.

14. The process according to claim 11, wherein the applicator is a brush that is less than 30 microns to facilitate fitting in grooves of the record.

15. The process according to claim 11, wherein the applicator (brush) is hand dried prior to the application of the ionizing surfactant on the recording media.

16. The process according to claim 11, further comprising polishing the recording media subsequent to the final cleaning cycle, wherein the step of polishing includes using a microfiber cloth to remove any remaining surface water on the recording media followed by a felt brush where a felt of less than 30 microns is used to polish the recording media grooves for removing any films or residues left over from the final cleaning cycle.

17. The process according the claim 11, wherein the ionizing surfactant is anti-fungal, anti-static, water-soluble wetting surfactant that ionizes the record changing charge on the recording media, thereby attracting the plasma wave created by a cavitation effect of the vibrating cleaning agent contained within the ultrasonic bath.

18. The process according to claim 11, wherein the rotation of the recording media partially immersed in the cleaning agent facilitates the entire surface area contact of the recording media, including all the grooves of the recording media, with the cleaning agent contained in the ultrasonic bath.

19. The process according to claim 11, wherein the pre-determined time period ranges from 2 minutes to 5 minutes, and wherein, depending on the materials to be subject to ultrasonic cleaning, temperature control from 95° F. and alerts thereof may be adjusted, and wherein 35 KHz is used as the preferred ultrasonic frequency, but said frequency may be adjusted depending on the materials to be cleaned and restored and upon the configuration of the tank and its support fixture configuration, and wherein a plurality of ultrasonic frequencies may additionally be used and selected in a fixed frequency or in a a sweeping range.

20. The process according to claim 11, wherein the cleaning agent is a distilled water or a mixture of water and a surfactant maintained at a temperature of 95° F. while the recording media is being rotated within the ultrasonic bath.
